(19) United States
(12) Patent Application Publication
(10) Pub. No.: US 2023/0241602 A1
(43) Pub. Date: Aug. 3, 2023

(54) Method and Control Unit for Producing a Carrier Element for Receiving a Sample Liquid, Carrier Element, Carrier Module, and Method for Using a Carrier Element

(71) Applicant: Robert Bosch GmbH, Stuttgart (DE)

(72) Inventors: Franz Laermer, Weil Der Stadt (DE); Daniel Sebastian Podbiel, Rutesheim (DE)

(21) Appl. No.: 17/999,664

(22) PCT Filed: May 19, 2021
(86) PCT No.: PCT/EP2021/063232

§ 371 Date: Nov. 22, 2022

(30) Foreign Application Priority Data
May 28, 2020 (DE) 10 2020 206 696.5

(51) Int. Cl. B01L 3/00

(52) U.S. Cl. CPC B01L 3/502707; B01L 2200/12; B01L 2300/165; B01L 2300/168; B01L 2300/0819

(57) ABSTRACT

A method for producing a carrier element for receiving a sample liquid is disclosed. The method includes a step of coating a carrier substrate with a light-sensitive polymer layer in order to obtain a coated carrier substrate, in particular wherein the carrier substrate has a hydrophilic surface quality. The method also includes an exposure and development step wherein the coated carrier substrate is exposed and developed in order to obtain a structured polymer layer. The method also includes a fluorination step, wherein the structured polymer layer on the carrier substrate is fluorinated in order to produce the carrier element for receiving the sample liquid, in particular wherein the structured polymer layer obtains a hydrophobic surface quality as a result of the fluorination step.

### PRIOR ART

The invention proceeds from a method and control unit for producing a carrier element for receiving a sample liquid, a carrier element, a carrier module, and a method for using a carrier element according to the genus of the independent claims. The subject matter of the present invention is also a computer program.

Microfluidic analysis systems, known as lab-on-chips (LoC), enable fully automated molecular diagnostic analysis of patient samples at a so-called point of care. The analysis of the sample takes place in an LoC cartridge, which is provided as a disposable part.

### DISCLOSURE OF THE INVENTION

In light of this, with the approach presented herein, an improved method, furthermore an improved control unit using this method, an improved carrier element, an improved carrier module, and an improved method for using a carrier element, and finally a corresponding computer program according to the main claims, are presented. By the measures listed in the dependent claims, advantageous developments and improvements of the apparatus specified in the independent claim are possible.

The approach presented herein creates a possibility to, for example, inexpensively produce a carrier element with an advantageous surface quality. Furthermore, this enables improved analysis of a sample liquid.

A method for producing a carrier element for receiving a sample liquid is presented, comprising a coating step, an exposure and development step, and a fluorination step. In the coating step, a carrier substrate is coated with a light-sensitive polymer layer in order to obtain a coated carrier substrate. The carrier substrate has a hydrophilic surface quality. In the exposure and development step, the coated carrier substrate is exposed and developed in order to obtain a structured polymer layer. In the fluorination step, the structured polymer layer arranged on the carrier substrate is fluorinated in order to produce the carrier element for receiving the sample liquid. In particular, the structured polymer layer obtains a hydrophobic surface quality as a result of the fluorination step.

For example, the carrier element may be realized in the form of a lab-on-chip designed to receive a sample liquid. For example, the sample liquid may be a body fluid, a secretion, or the like as a patient sample to be analyzed, for example. For example, the carrier substrate may be realized as a base material having particular desired properties and carrying or receiving further components of the carrier element. For example, the light-sensitive polymer layer may be formed as a plastic ply or plastic layer, such as a photoresist. In this case, for example, this polymer layer can first be applied to the carrier substrate in liquid form and subsequently cured, for example by tempering. In the exposure step, the coated carrier substrate, i.e., here especially the polymer layer, may, for example, be exposed to light, which, for example, comprises electromagnetic radiation, which may also have wavelengths that extend beyond a wavelength range of visible light. Such radiation may comprise, for example, ultraviolet radiation (UV) or X-radiation. By exposure and development, advantageously exposed regions of the polymer layer on the coated carrier substrate may be selectively altered in their solubility in a solvent and subsequently removed so that the structured polymer layer is advantageously obtained. Advantageously, in the fluorination step, the carrier substrate and, additionally or alternatively, the polymer layer or a surface of the polymer layer is brought into contact with, for example, a fluorine-containing material, substance, plasma and, additionally or alternatively, a solution. Fluorination can thus be understood to mean bringing a surface of the polymer layer in contact with a fluorine-containing material, substance, plasma and, additionally or alternatively, a solution. Advantageously, as a result, the surface quality of the structured polymer layer is realized more hydrophobic than it was before. Overall, a local wetting of the carrier substrate with the sample liquid can advantageously be enabled since the carrier substrate, in combination with the structured polymer layer, can have hydrophobic regions and hydrophilic regions.

According to one embodiment, in the coating step, the carrier substrate can be coated, which may at least partially be formed from a semiconductor material, in particular from a silicon-containing material. Especially, a surface of the semiconductor material may be coated with the light-sensitive polymer layer. Advantageously, the polymer layer of the coated carrier substrate can have a hydrophobic surface quality as a result.

The method may comprise a step of structuring the carrier substrate in order to obtain at least one recess in the carrier substrate. Advantageously, the carrier substrate may, for example, be etched in order to obtain the at least one recess. The recess may, for example, also be referred to as a volume structure. In this way, fluid channels or fluid chambers may, advantageously and technically easily, be formed in the recess in order to analyze the sample liquid.

According to one embodiment, in the structuring step, a passivation layer may be generated on at least one side wall of the at least one recess. In addition, in the fluorination step, the passivation layer arranged on at least one side wall of the recess may be removed at least partially. Advantageously, on the side wall of the recess, a layer may, for example, form the side wall polymers, which are at least partially removed in the fluorination step, for example. As a result, at least one surface within the recess, which may for example also be referred to as a microcavity, may advantageously be formed hydrophilic.

In the coating step, according to one embodiment, a substrate having an oxide layer and, additionally or alternatively, carrier substrate coated with an adhesive-agent layer may be used as the carrier substrate. For example, the adhesive agent may be formed as an alkyl trichlorosilane or as a hexamethyldisilazane (HMDS), which can advantageously prevent the polymer layer from detaching from the carrier substrate. This means that in particular in the case that the substrate comprises an oxide layer, the adhesive agent may be formed, for example, as an adhesive agent between the carrier substrate and the polymer layer.

Furthermore, the method may comprise a step of applying a further light-sensitive polymer layer and a step of further exposing and developing the further polymer layer in order to obtain a further structured polymer layer. The further polymer layer may advantageously be formed from the same material as the polymer layer. In this case, the (first) polymer layer may be used to structure an oxide layer on the substrate. Hereafter, the (first) polymer layer is, for example, removed and the further polymer layer is subsequently applied to the substrate with the structured oxide layer. The oxide layer and the further polymer layer then, for example, serve together as a resist for an etching step for the volume structuring of the substrate. The further polymer layer may then be fluorinated, for example, and thus serve to form a layer having a hydrophobic surface quality. The spatial configuration of the volume structuring, which was also defined by the oxide layer (i.e., the first polymer layer), can thus advantageously take place partially independently of the generation and the spatial configuration of the hydrophobic layer. In this way, structuring of the further polymer layer may be performed that is different from the type of structuring of the polymer layer so that a degree of flexibilization can be increased in the structuring.

According to one embodiment, the method may comprise a further structuring step after the further exposure and development in order to obtain at least one further recess in the carrier substrate. A microcavity may advantageously be produced thereby.

In a depositing step, a layer may be deposited after the fluorination step in order to alter and, additionally or alternatively, cover a surface of the carrier substrate. Advantageously, this can achieve that the recess as well as its side wall is formed hydrophilic by the deposited layer, and the surface of the polymer layer, on the other hand, is formed hydrophobic. As a result, a capillary effect and, additionally or alternatively, an accidental mixing of the sample liquid introduced into a plurality of recesses can advantageously be avoided.

This method can be implemented, for example, in software or hardware or in a mixed form of software and hardware, for example in a control unit.

The approach presented here furthermore creates an apparatus which is designed to carry out, actuate, or implement in corresponding devices the steps of a variant of a method presented here. Even this embodiment variant of the invention in the form of an apparatus or a control unit can quickly and efficiently achieve the object underlying the invention.

For this purpose, the apparatus may comprise at least one computing unit for processing signals or data, at least one storage unit for storing signals or data, at least one interface to a sensor or an actuator for reading sensor signals from the sensor or for outputting control signals to the actuator, and/or at least one communication interface for reading or outputting data embedded in a communication protocol. For example, the computing unit may be a signal processor, a microcontroller, or the like, wherein the storage unit may be a flash memory, an EEPROM, or a magnetic storage unit. The communication interface may be designed to read or output data in a wireless and/or wired manner, wherein a communication interface capable of reading or outputting wired data may, for example, electrically or optically read said data from a corresponding data transmission line or output them into a corresponding data transmission line.

An apparatus is understood in the present case to mean an electrical device that processes sensor signals and outputs control signals and/or data signals as a function thereof. The apparatus may comprise an interface, which may be formed by hardware and/or software. In a hardware design, the interfaces can be part of a so-called system ASIC, for example, which contains various functions of the control unit. However, it is also possible that the interfaces are separate, integrated circuits or at least partially consist of discrete structural elements. In a software design, the interfaces may be software modules that are present, for example, on a microcontroller in addition to other software modules.

In an advantageous configuration, the apparatus controls a method for producing a carrier element for receiving a sample liquid. For this purpose, the apparatus may, for example, access sensor signals, such as a coating signal for coating a carrier substrate with a light-sensitive polymer layer, an exposure signal for exposing and developing the coated carrier substrate, and a fluorine signal for fluorinating the structured polymer layer arranged on the carrier substrate. The actuation takes place via actuators, such as a provisioning unit designed to provide coating, exposure, and fluorination. The individual process steps can be carried out according to the prior art in various systems specially designed for this purpose, such as a spin coater (coating), a mask writer (exposure) and a low-pressure plasma system (fluorination). It would also be conceivable that the substrates/wafers are (partially) automatically transferred between the various systems by wafer-handling apparatuses during the method.

A computer program product or a computer program with program code that can be stored on a machine-readable carrier or storage medium, such as a semiconductor memory, a hard disk memory, or an optical memory, and that is used for carrying out, implementing, and/or actuating the steps of the method according to one of the embodiments described above is advantageous as well, in particular when the program product or program is executed on a computer or an apparatus.

Furthermore, a carrier element for receiving a sample liquid is presented, wherein the carrier element comprises a carrier substrate having a hydrophilic surface quality and a polymer layer arranged or arrangeable on the carrier substrate and having a hydrophobic surface quality.

For example, the carrier element may be referred to as a lab-on-chip (LoC) or as a microarray. The carrier element can, for example, be used for a carrier module. Advantageously, the carrier element may be used to, for example, analyze the sample liquid obtained, for example, from a patient's body fluid to be examined.

Furthermore presented is a carrier module comprising a carrier element in a previously mentioned variant for receiving a sample liquid and a cover element which is connectable or connected to the carrier element and designed to apply the sample liquid to the carrier element.

The carrier module may advantageously be realized as a disposable cartridge.

According to one embodiment, a method for using a carrier element in a previously mentioned variant is also presented, wherein during the use of the carrier element, a sample liquid is brought into contact with the fluorinated structured polymer layer, and additionally or alternatively wherein the sample liquid is brought into contact with a surface of the carrier substrate.

Advantageously, the sample liquid may be received by the recess of the carrier element.

Exemplary embodiments of the approach presented here are illustrated in the drawings and explained in more detail in the following description. The figures show:

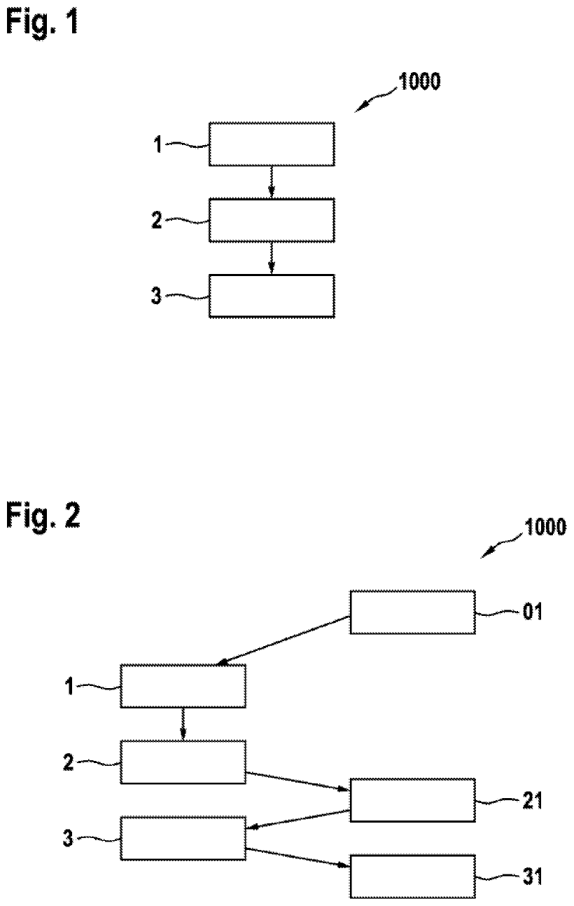

FIG. 1 a flow chart of a method for producing a carrier element for receiving a sample liquid according to one exemplary embodiment;

FIG. 2 a flow chart of one exemplary embodiment of a method for producing a carrier element for receiving a sample liquid;

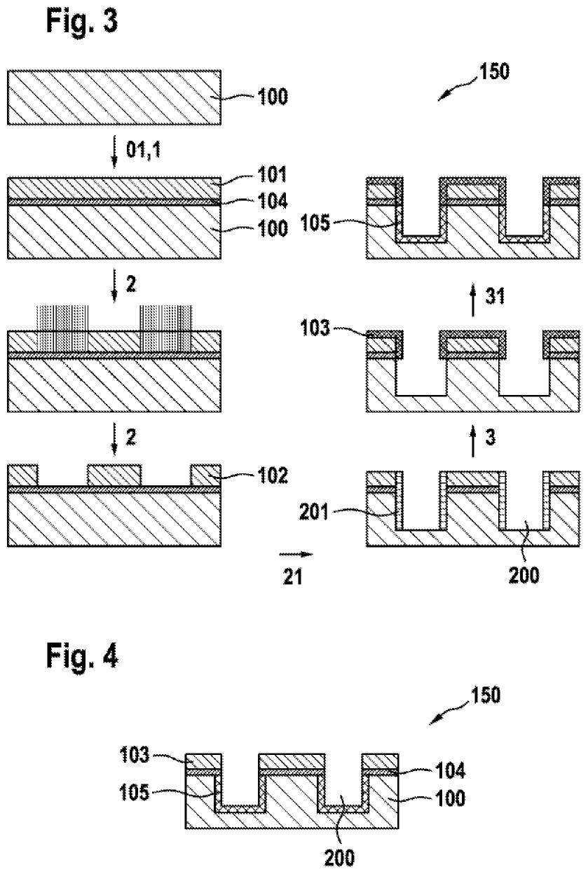

FIG. 3 a schematic illustration of various intermediate products of a carrier element according to one exemplary embodiment during a method for producing the carrier element for receiving a sample liquid;

FIG. 4 a schematic cross-sectional view of a carrier element according to one exemplary embodiment;

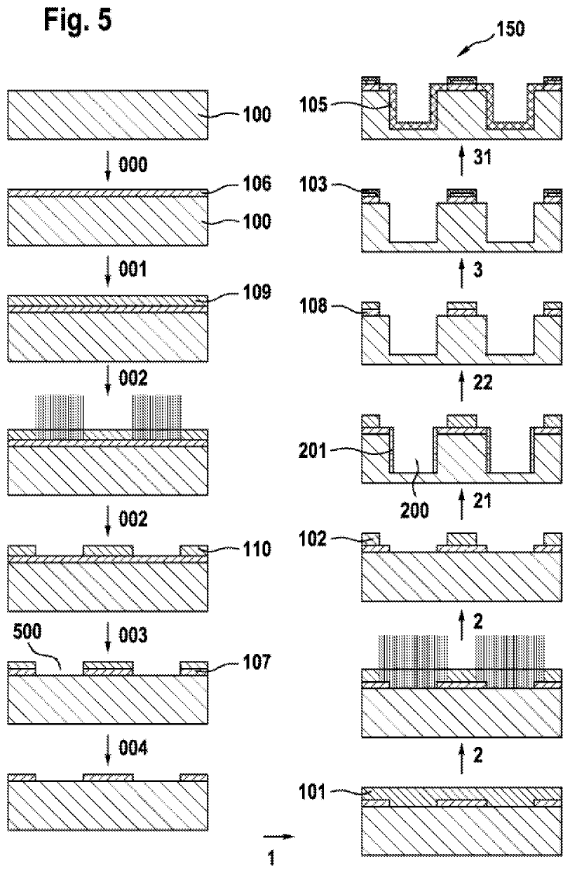

FIG. 5 a schematic illustration of various intermediate products of a carrier element according to one exemplary embodiment during a method for producing the carrier element for receiving a sample liquid;

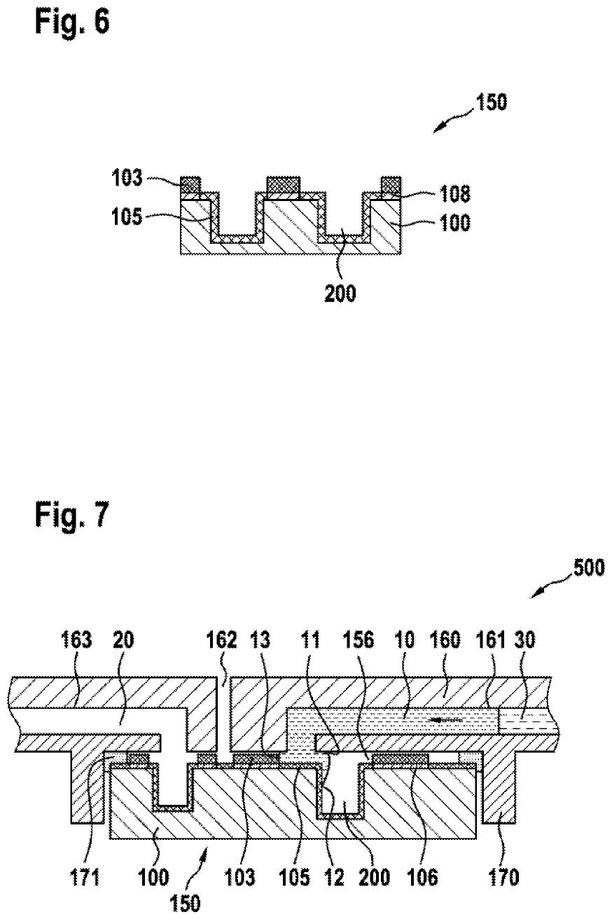

FIG. 6 a schematic cross-sectional view of a carrier element according to one exemplary embodiment;

FIG. 7 a schematic cross-sectional view of a carrier module according to an exemplary embodiment;

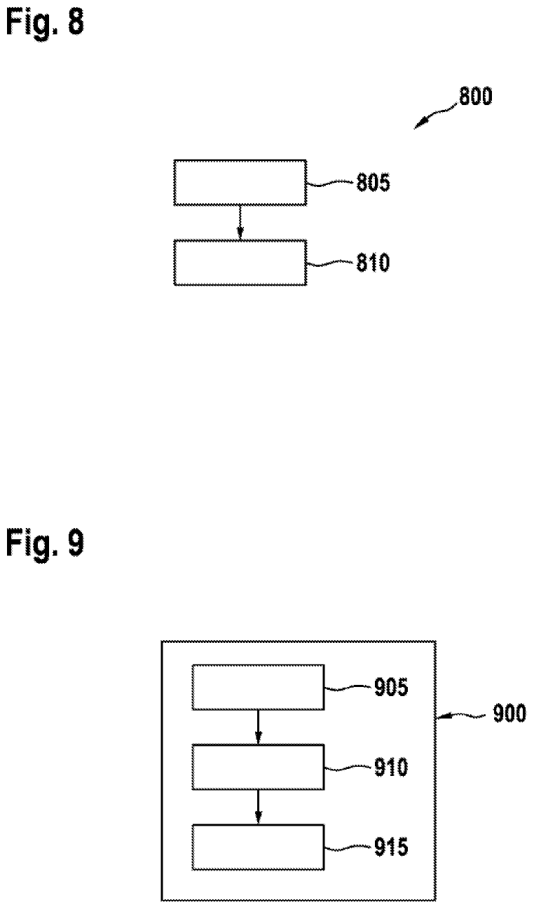

FIG. 8 a flow chart of a method for using a carrier element according to one exemplary embodiment; and

FIG. 9 a block diagram of an apparatus according to one exemplary embodiment.

In the following description of favorable exemplary embodiments of the present invention, identical or similar reference signs are used for the elements shown in the various figures and acting similarly, wherein a repeated description of these elements is dispensed with.

FIG. 1 shows a flow chart of a method 1000 for producing a carrier element 100 for receiving a sample liquid according to one exemplary embodiment. The carrier element to be produced and/or produced by the method 1000 is, for example, formed as a microarray in order to receive the sample liquid. The sample liquid is, for example, realized as an aqueous solution, which is in particular obtained from a biological substance of, for example, human origin. The substance for obtaining the sample liquid is, for example, realized as a body fluid, a smear, a secretion, a sputum, a tissue sample, or is obtained from an apparatus with attached sample material. Located in the sample liquid are, in particular, species of medical, clinical, diagnostic, or therapeutic relevance, such as bacteria, viruses, cells, circulating tumor cells, cell-free DNA, proteins, as well as other biomarkers or constituents from the objects mentioned. In particular, the sample liquid according to this exemplary embodiment is a master mix for carrying out an amplification reaction, such as a polymerase chain reaction or an isothermal amplification reaction.

In this case, the carrier element is, for example, designed to be used in conjunction with a carrier module.

The method 1000 comprises a step 1 of coating a carrier substrate with a light-sensitive polymer layer, which is formed as a photoresist, for example. The carrier substrate in this case has a hydrophilic surface quality. In an exposure and development step 2, the carrier substrate is exposed and developed in order to obtain a structured polymer layer. For this purpose, electromagnetic radiation that also goes beyond a visible range can, for example, be used. The method 1000 furthermore comprises a step 3 of fluorinating the structured polymer layer arranged on the carrier substrate, for example, by bringing it into contact with a plasma with a fluorine-containing material in order to prepare the carrier element for receiving the sample liquid. In so doing, the structured polymer layer obtains a hydrophobic surface quality. According to this exemplary embodiment, the carrier substrate is formed from a semiconductor material, in particular from a silicon-containing material. The carrier substrate is, for example, also formed as a substrate having an oxide layer and/or an adhesive-agent layer.

Generally, microfluidic analysis systems, which are, for example, referred to as lab-on-chips (LoCs), enable fully automated molecular diagnostic analysis of, for example, patient samples at the point of care. The analysis of the sample liquid takes place in an LoC cartridge, which is provided as a disposable part. Polymers are in particular suitable for a cost-effective production of LoC cartridges. High-throughput methods, such as injection molding or laser radiation welding, permit cost-efficient mass production. However, LoC cartridges produced in this way have limitations or disadvantageous properties due to manufacturing technique and material. Accordingly, the achievable structure sizes are limited in terms of production technology, the thermal conductivity of polymers is only low and there is no intrinsic electrical functionalizability, such as in semiconductors that permit doping. Moreover, the mostly non-polar polymer surfaces have a rather hydrophobic quality and thus poor wettability for in particular aqueous solutions. In order to overcome these limitations and to be able to provide extended microfluidic functionalities in an LoC cartridge, an integration of components made of other materials which have advantageous properties is suitable. In particular, an integration of microstructured silicon components appears to be advantageous. The material silicon has very good microstructurability, a high thermal conductivity as well as semiconductive properties. However, for the provision of a microfluidic component, which is referred to herein as a carrier element, with a desired microfluidic functionality, a controlled adjustment of the wetting properties of the surface is usually additionally advantageous.

In light of this, method 1000 is therefore presented, which allows a local adjustment of the wetting properties of the carrier substrate, in particular silicon, and primarily on the basis of a photolithographic technique. Moreover, in addition to adjusting the wetting properties, the method 1000 enables microstructuring of the carrier substrate using a single photolithographic process step. In this way, a particularly inexpensive production of three-dimensional carrier elements with locally adjusted wetting properties of the surface is possible. A carrier element produced by the approach presented herein can furthermore be used as a constituent of a carrier module that allows the use of the carrier element, for example in combination with a polymer-based LoC cartridge.

A method 1000 is therefore presented herein that permits the photolithographic production of microfluidic parts and/or components, in particular based on silicon, that have a locally adjusted wetting behavior for liquids, in particular for aqueous solutions. In a continuation of method 1000, in addition to a local adjustment of the wetting behavior of the surface, a volume structuring of the carrier substrate also takes place. The method 1000 is characterized, for example, by the generation of a fluorinated surface, in particular the fluorinated microstructured polymer layer, which has a hydrophobic, i.e., water-repellent, surface quality as opposed to the possibly suitably modified substrate surface, which preferably has a hydrophilic quality.

In other words, the method 1000 for producing a microfluidic component, also referred to as a carrier element, produces the carrier element having locally adjusted wetting properties of a surface of the carrier substrate. In the coating step 1, the light-sensitive polymer layer is applied to the carrier substrate, e.g., silicon, for example by spin-coating onto the carrier substrate, and subsequently heated, which is also referred to as “baking”, in order to remove solvent residues. In the exposure and development step 2, the polymer layer is locally exposed, for example by means of a mask having the structures to be generated or their negative, or exposed using a direct-writing method, for example by laser beam direct writing. For example, the exposed polymer layer is developed in a suitable solvent so that there is subsequently a structured polymer layer on the substrate surface. In the fluorination step 3, the structured polymer layer is fluorinated in order to render its surface particularly hydrophobic, which means repellent to aqueous solutions, for example by treatment in a plasma having proportions of a fluorine-containing compound, such as tetrafluoromethane (CF4).

According to this exemplary embodiment, step 3 of fluorinating the polymeric resist represents a possibility in which fluorination on the top side of the wafer serves to selectively locally adjust the wetting properties in these regions between the recesses of a targeted local, for example, in a manner photolithographically defined. By the approach presented herein, passive microfluidic structures, such as channels, multiplexers, various compartmentalization apparatuses, and/or separation units, can be realized based on silicon and by providing suitable wetting properties that are useful, for example, for exploiting capillary effects.

FIG. 2 shows a flow chart of one exemplary embodiment of a method 1000 for producing a carrier element for receiving a sample liquid. The flow chart shown here contains steps 1, 2, 3 of the method 1000 described in FIG. 1 and, according to this exemplary embodiment, is to be understood as an extension of the method 1000 described in FIG. 1.

Furthermore, in the coating step 1, a substrate having an oxide layer and/or a carrier substrate 100 coated with an adhesive-agent layer 104 may be used as the carrier substrate 100.

According to this exemplary embodiment, the method 1000 thus comprises an optional step 01 of applying an adhesive agent to the carrier substrate 100. The application step 01 is carried out according to this exemplary embodiment prior to the coating step 1. Furthermore optionally, the method 1000 comprises a step 21 of structuring the carrier substrate in order to obtain at least one recess in the carrier substrate. This means that the structuring is, for example, carried out by means of an etching process so that the carrier substrate has a volume structure, for example. According to this exemplary embodiment, a passivation layer is applied to a side wall of the at least one recess, for example in a step of deep reactive ion etching. The side wall polymers that form the passivation layer and are arranged on a side wall of the recess are, for example, subsequently at least partially removed in the fluorination step 3. Furthermore, according to this exemplary embodiment, the method 1000 comprises a step 31 of depositing a layer in order to alter and/or cover a surface of the carrier substrate. The depositing step 31 is carried out according to this exemplary embodiment after the fluorination step 3 and describes, for example, the depositing of a substance on the carrier substrate.

In other words, prior to the coating step 1, the surface of the carrier substrate is provided with, for example, the adhesive agent in the application step 01. In this way, a more stable bond of the polymer layer to the surface of the carrier substrate can be achieved. For example, a silicon surface may be pretreated with hexamethyldisilazane (HMDS) or an alkyl trichlorosilane. In this way, the polymer layer can, in particular, be prevented from undesirably detaching from the surface of the carrier substrate as a result of mechanical or chemical stress. Furthermore, the surface of the carrier substrate according to this exemplary embodiment comprises a hydrophilic surface quality. As a result, wetting of the substrate surface with aqueous solutions is favored, for example. Due to the hydrophobic character of the fluorinated polymer layer, the latter acts as a barrier to, for example, aqueous phases. As a result, controlled local wetting of the substrate surface can be achieved. For example, the locally adjusted surface quality achieves selective wettability of the test structure with an aqueous solution.

Furthermore, according to this exemplary embodiment, the polymer layer is used as a resist or a mask for the structuring step 21, for example by means of an etching process, for the volume structuring of the carrier substrate. For example, a silicon substrate is structured by means of a deep reactive ion etching method. In the depositing step 31, selective deposition on the surface of the silicon substrate is carried out additionally, but optionally, for example by means of a chemical vapor deposition (CVD), atomic layer deposition (ALD), by means of attaching a self-assembled monolayer (SAM) or by using a silane compound, in particular a polyethylene glycol silane compound. A modified substrate surface with an adjusted wetting behavior and, where appropriate, a particularly high biocompatibility is thereby produced, for example.

In the coating step 1, the polymer-based light-sensitive resist referred to herein as the polymer layer is applied to the carrier substrate formed as a silicon substrate, for example by spin-coating a lacquer and subsequent heating in order to remove solvent residues. Optionally, prior to coating, the silicon surface is treated with an adhesive agent, for example hexamethyldisilazane (HMDS) or an alkyl trichlorosilane, such as octadecyltrichlorosilane. By the step 2 of exposing and developing the polymer layer, a photolithographic definition of the locally present wetting properties and optionally a mask for an etching process is formed. By etching the silicon substrate in the structuring step 21, for example by means of deep reactive ion etching, a defined microstructuring is achieved in order to, for example, produce cavities or microfluidic chambers and channels, also referred to as recesses.

In the fluorination step 3, the carrier substrate is treated in a plasma with a fluorine-containing compound, in particular with tetrafluoromethane (CF4), in order to achieve fluorination of the polymer surface of the structured polymer layer and, where appropriate, suitable termination of the remaining substrate surface. Optionally, in the depositing step 31, a selective coating of the bare silicon surface not covered by the polymer layer additionally takes place, for example by chemical vapor deposition (CVD) or atomic layer deposition (ALD) or a wet chemical treatment. As a result, hydroxylation of the silicon surface or the production of a particularly biocompatible surface is, for example, achieved by a covalent attachment of a molecule such as polyethylene glycol (PEG). Subsequently, the silicon substrate is optionally separated by, for example, mechanical sawing, laser-based dicing (“Maho-Dicing”), or by breaking along predetermined breaking points, which have been introduced into the substrate by etching, for example.

By using a photolithographic method, microfluidic structures with locally adjusted wetting properties of the surface are produced with a very high precision and very small structural sizes in the μm range, on the one hand; on the other hand, highly parallel processing on large-area substrates is possible so that cost-effective manufacturability of the carrier element is thus given, for example.

By using a polymer-based light-sensitive polymer layer as both a mask for the etching process and as a basis for generating a hydrophobic coating of the substrate top side, a single lithography step is still sufficient in order to achieve both a defined microstructuring of the silicon substrate and to enable an adjustment of the wetting behavior in the regions located on the top side of the substrate between the etched structures. By the hydrophobization of the carrier substrate provided by the method 1000, a fluidic cross-talk is in particular advantageously prevented, for example, between adjacent structures introduced into the silicon substrate via the structuring step 21. Overall, the method 1000 makes it possible to manufacture microstructured silicon components with locally adjusted wetting behavior in a particularly simple and cost-efficient manner. According to this exemplary embodiment, tetrafluoromethane (CF4) plasma treatment following the etching process in the fluorination step 3 achieves both fluorination of the polymer surface and cleaning of the structures etched into the silicon substrate. According to this exemplary embodiment, this results on the one hand in the polymer surface exhibiting a particularly hydrophobic, i.e., water-repellent, behavior and on the other hand, a cleaning and/or termination of the surface of the structure etched into the silicon substrate is simultaneously achieved. In particular, the CF4 plasma treatment, for example, at least partially removes side wall polymers originating from a deep reactive ion etching process and produces a hydrophilic silicon surface. Furthermore, according to this exemplary embodiment, fluorination of the polymeric photoresist surface in the subsequent depositing step 31 achieves a selective coating of the silicon surface not covered with the structured fluorinated polymer layer, for example by chemical vapor deposition (CVD), atomic layer deposition (ALD), or by another chemical treatment. As a result, the wetting behavior of the silicon surface not covered by the polymeric resist is, for example, further adjusted and/or a particularly good biocompatibility of the structures generated is produced.

FIG. 3 shows a schematic illustration of various intermediate products of a carrier element 150 according to one exemplary embodiment during a method for producing the carrier element 150 for receiving a sample liquid. According to this exemplary embodiment, the carrier element 150 shown here is produced by means of the method as described in FIG. 2. According to this exemplary embodiment, the partial result after each step 01, 1, 2, 21, 3, 31 of the method 1000 is depicted accordingly.

According to this exemplary embodiment, the carrier substrate 100 is coated with the polymer layer 101 in the coating step 1. According to this exemplary embodiment, the adhesive agent 104 is arranged between the carrier substrate 100 and the polymer layer. After the exposure and development step 2, the carrier element 150 comprises the structured polymer layer 102. That is to say, according to this exemplary embodiment, the polymer layer 101 is removed during development at the position that the light rays strike during exposure, in order to obtain the structured polymer layer 102. In the structuring step 21, the carrier substrate 100 is structured in that, for example, recesses 200 are etched into the carrier substrate 100. The production of the recesses takes place in particular by a step of deep reactive ion etching, wherein a passivation layer 201 in the form of side wall polymers is applied to the carrier substrate 100 and/or to the structured polymer layer 102. In the fluorination step 3, the side wall polymers are removed (at least partially) and the structured polymer layer 102 is fluorinated in order to obtain, for example, a fluorinated polymer layer 103 that is formed hydrophobic. In the depositing step 31, a layer 105 is deposited onto a surface of the recesses 200 that is hydrophilic.

In other words, used as the carrier substrate 100 is a silicon wafer which is pretreated 01 with hexamethyldisilazane (HMDS) as the adhesive agent 104 and to which a photoresist/polymeric resist 101 is applied by spin-coating in the coating step 1. After local exposure in the exposure and development step 2, the structuring step 21 takes place, for example in the form of a deep reactive ion etching process for the volume structuring of the carrier substrate 100, also referred to as silicon substrate. For example, subsequent treatment of the carrier substrate 100 in, for example, a low-pressure plasma with proportions of CF4 in the fluorination step 3 achieves fluorination of the remaining polymer layer 103 and at least partial removal of the passivation layer 201 formed as side wall polymers at the surface of the recesses 200, which are also referred to as an etched structure or as volume structuring. Subsequently, the application of the layer 105 as a selective deposition may takes place in the step 31 of depositing on the carrier substrate 100, for example, by means of chemical vapor deposition (CVD), atomic layer deposition (ALD), attaching a self-assembled monolayer (SAM), or by using a silane compound, in particular a polyethylene glycol silane compound. The polymer surface of the fluorinated polymer layer 103, also referred to as the photoresist, remains unaffected by the previous fluorination 3 of the surface so that selectivity of the depositing step 31 is achieved.

FIG. 4 shows a schematic cross-sectional view of a carrier element 150 according to one exemplary embodiment. The carrier element 150 may correspond or at least be similar to the carrier element 150 described in FIG. 3 and may accordingly have been produced by a method as described in one of FIGS. 1 and/or 2.

According to this exemplary embodiment, the carrier element 150 is formed as a microfluidic component. The carrier element 150 consists of the microstructured carrier substrate 100, which at its top side has the structured and fluorinated polymer layer 103 applied to the carrier substrate 100 by means of the adhesive agent 104. Furthermore, in the substrate 100 are the recesses 200, the surface of which comprises a hydrophilic layer 105.

The carrier element 150 is designed to receive the sample liquid. For this purpose, the carrier element 150 comprises the carrier substrate 100 having a hydrophilic surface quality and the fluorinated polymer layer 103 arranged or arrangeable on the carrier substrate and having the hydrophobic surface quality.

The carrier substrate 100 is, for example, formed from a silicon-containing material having, for example, a thickness of between 100 μm and 3 mm, preferably between 300 μm and 1000 μm. The polymer layer 103 has, for example, a thickness of between 500 nm and 10 μm, but preferably between 1 μm and 5 μm. According to this exemplary embodiment, the polymer layer 103 is realized or realizable as a phenolic resin, for example. The at least one recess 200 of the carrier substrate 100 has, for example, a structure size that is, for example, between 500 nm and 30 mm, but preferably between 5 μm and 1 mm.

Furthermore, the carrier element 150 has, for example, a size that is between 1×1 mm² and 100×100 mm². According to this exemplary embodiment, the carrier element 150 preferably has a size of between 3×3 mm² and 10×10 mm².

FIG. 5 shows a schematic illustration of various intermediate products of a carrier element 150 according to one exemplary embodiment during the performance of a method for producing the carrier element 150. According to this exemplary embodiment, the carrier element 150 shown here is produced by means of the method as described in one of FIGS. 1 to 3. The method is shown in this case extended so that, according to this exemplary embodiment, further optional steps 000, 001, 002, 003, 004, 22 of the method 1000 are described in more detail below in addition to the steps 01, 1, 2, 21, 3, 31 described in at least one of the preceding figures.

The carrier substrate 100 according to this exemplary embodiment comprises the oxide layer 106 arranged on the carrier substrate 100. Furthermore optionally, an adhesive agent may additionally be applied to the oxide layer in order to achieve better bonding of the polymer layer to the substrate with the oxide layer. According to this exemplary embodiment, the partial results of the individual steps of the method are depicted. In addition to the method steps described in FIGS. 1 and/or 2, the method furthermore comprises a step 001 of applying a further light-sensitive polymer layer 109 to the carrier substrate 100. According to this exemplary embodiment, the further polymer layer 109 has the same light-sensitive properties as the polymer layer 101 with which the carrier substrate 100 is coated according to this exemplary embodiment at a later date.

The method furthermore comprises a step 002 of further exposing and developing the further polymer layer 109 in order to obtain a further structured polymer layer 110. In addition, the method according to this exemplary embodiment furthermore comprises a further structuring step 003 after the further exposure and development step 002 in order to obtain at least one structuring 500 of the oxide layer 106 on the carrier substrate 100. More precisely, in the further structuring step 003, the oxide layer 106 according to this exemplary embodiment is partially opened so that a structured oxide layer 107 is present. Furthermore optionally, according to this exemplary embodiment, the further structured polymer layer 110 is removed in a removal step 004 before the carrier substrate 100 is coated in step 1 of coating with the polymer layer 101 as described in one of FIGS. 1 to 4. Subsequently, according to this exemplary embodiment, the exposure and development step 2 as well as step 21 of structuring the carrier substrate 100 also follow. Optionally, the method according to this exemplary embodiment comprises a step 22 of opening the structured and partially opened oxide layer 107 by utilizing the structured polymer layer (102) in order to obtain the opened oxide layer 108 which, according to this exemplary embodiment, after step 22, for example, has the same dimensions as the structured polymer layer 102. According to this exemplary embodiment, in the fluorination step 3, the structured polymer layer 102 is subsequently fluorinated in order to render the structured polymer layer 102 hydrophobic. Finally, in the depositing step 31, the layer 105 is deposited with a hydrophilic surface quality on the carrier substrate 100.

In other words, for example, in a generating step 000, the oxide layer 106 is first generated on the carrier substrate 100. This is, for example, possible by thermal oxidation or chemical vapor deposition. After step 001 of applying the further polymer layer 109, which can be referred to as a polymeric resist, and subsequently further exposing and developing 002 the further polymer layer 109, the thereby further structured polymer layer 110 is used for the defined opening of the oxide layer 106, which according to this exemplary embodiment is brought about in the further structuring step 003. The opened oxide layer 107 serves in the later structuring step 21 as a mask for the volume structuring of the carrier substrate 100.

After step 004 of removing the further structured polymer layer 110, the polymer layer 101 is applied to the carrier substrate 100 with the structured oxide layer 107 in the coating step 1. The polymer layer 101 serves in a later fluorination step 3 to generate the structured fluorinated polymer layer 103 on the carrier substrate 100. For this purpose, in the exposure and development step 2, the polymer layer 101 is first exposed locally and subsequently developed.

According to this exemplary embodiment, the partially opened oxide layer 107 and/or the structured polymer layer 102 is used as a mask for an etching step, i.e., for the structuring step 21 for the volume structuring 200 of the carrier substrate 100, for example by means of deep reactive ion etching. After step 22 of opening the oxide layer 107 in the regions of the carrier substrate 100 not covered by the structured polymer layer 102, step 3 of fluorinating the structured polymer layer 102 in, for example, a CF4 plasma takes place in order to obtain the fluorinated polymer layer 103. Finally, via a selective deposition in the deposition step 31, the functional layer 105 is generated on the free silicon surface of the carrier substrate 100, for example by means of chemical vapor deposition (CVD), atomic layer deposition (ALD), or attaching a self-assembled monolayer (SAM) or by using a silane compound, in particular a polyethylene glycol silane compound, in order to advantageously generate a biocompatible, hydrophilic surface. In particular, in addition to the recess 200, the carrier element 150 additionally comprises a locally adjusted wetting behavior, which is defined independently of the shape of the recess 200 of the carrier substrate 100. In an advantageous exemplary embodiment of the carrier element 150, also referred to as a component, regions of the carrier element, e.g., the chip top side, adjacent to the recesses 200 or cavities are, for example, designed with a hydrophilic layer 105 in order to facilitate the introduction of, for example, aqueous liquids into the recesses 200 or cavities in the carrier substrate 100.

In an advantageous development of the method shown here, an additional second photolithographic step, for example, achieves a locally defined adjustment of the wetting properties on the top side of the carrier element 150. In this way, a comparable wetting behavior as in the structures generated in the structuring step 21 is achieved on the top side in defined subregions. In particular, a hydrophilic surface quality is produced which allows good wettability of these subregions of the top side with an aqueous solution, while a hydrophobic surface quality in the remaining regions of the top side prevents wetting with an aqueous solution. In this way, even more complex microfluidic structures can be generated in the carrier element 150. In a particularly advantageous manner, such a component is used in combination with a further component, in particular consisting of a polymer material.

According to this exemplary embodiment, the method in particular allows the manufacture of silicon chips with microfluidic microcavity arrays that have microcavities with a hydrophilic surface quality and have a hydrophobic chip top side in predefined subregions. The hydrophilic microcavities have a high affinity to aqueous solutions on the one hand; on the other hand, after the microcavities previously filled with an aqueous phase are sealed with a second phase, for example with an oil, such as mineral oil, paraffin oil, or silicone oil, a PDMS prepolymer, or a fluorinated hydrocarbon, such as Fomblin, 3M Fluorinert FC-40, FC-70, or Novec 7500, aliquoting of the aqueous phase in the microcavities is achieved, where appropriate.

FIG. 6 shows a schematic cross-sectional view of a carrier element 150 according to one exemplary embodiment. The carrier element 150 shown here may correspond or at least be similar to the carrier element 150 described in FIG. 5. According to this exemplary embodiment, the carrier element 150 shown here can furthermore be produced in a method as described in FIG. 5. The carrier element 150 according to this exemplary embodiment comprises a structured oxide layer 108, a fluorinated polymer layer 103 arranged on the structured oxide layer 108, and a hydrophilic layer 105 on bare surfaces of the carrier substrate 100. Furthermore, the carrier element 150 comprises at least one recess 200. This means that the carrier element 150 shown here may be generated as an end product of the method described in FIG. 5, which in turn is to be understood as an extension of the methods described in FIGS. 1 and/or 2.

In other words, a schematic illustration of a cross-section of the microfluidic component referred to as the carrier element 150, which was produced according to the advantageous development of the method described in FIG. 5, is depicted. The carrier element 150 consists of a microstructured carrier substrate 100 in which recesses 200 are located. The recesses have a hydrophilic and, in particular, biocompatible layer 105, which is also referred to as surface functionalization. A top side of the carrier element 150 has heterogeneous, i.e., hydrophilic and hydrophobic, regions that have different wetting behavior for aqueous solutions, for example. The hydrophobic subregions of the top side of the carrier element 150 have a fluorinated polymer layer 103, while the hydrophilic regions have the same layer 105 as the recesses 200 introduced into the carrier substrate 100. Due to the special quality of the carrier element 150 in terms of geometry and surface properties, it can be used for capillary force-assisted processing of a sample liquid in a microfluidic system.

FIG. 7 shows a schematic cross-sectional view of a carrier module 500 according to an exemplary embodiment. The carrier module 500 comprises a carrier element 150 for receiving a sample liquid 10 and a cover element 160 which is connectable or connected to the carrier element 150 and designed to apply the sample liquid 10 to the carrier element 150. The carrier module 500 is formed as a disposable cartridge, for example. The carrier element 150 shown here may, for example, correspond or at least be similar to the carrier element 150 described in one of FIGS. 3 to 6. According to this exemplary embodiment, the carrier element 150 can be produced by a method as described, for example, in one of FIGS. 1, 2, 3, and/or 5.

According to this exemplary embodiment, the carrier element 150 with locally adjusted wetting properties of the surface is used in combination with at least one further component, which is referred to herein as cover element 160, for example a structured polymer substrate. The cover element is, for example, formed from a polymer, such as polycarbonate, polypropylene, polyethylene, cycloolefin copolymer, or polymethyl methacrylate, and can be produced, for example, by injection molding. According to this exemplary embodiment, a relative position of the carrier element 150 is sufficiently restricted with respect to the position of the cover element 160 in order to enable transport of at least the one sample liquid 10 between the cover element 160 and the carrier element 150. According to this exemplary embodiment, the cover element 160 and the carrier element 150 form the carrier module 500, which is, for example, realized as a disposable cartridge.

Optionally, the cover element 160 has at least one adjustment element 170 for this purpose, which accurately fixes the relative position of the carrier element 150 in relation to the cover element 160. According to this exemplary embodiment, the carrier element 150 is optionally fixedly connected to the cover element 160 via, for example, an adhesive connection 171. Furthermore, the cover element 160, in particular, has at least one channel 161 for transporting the sample liquid 10 to the carrier element 150 via a space 156 arranged between the carrier element 150 and the cover element 160. According to this exemplary embodiment, the space 156 is adjoined by the fluorinated polymer layer 103 with which the carrier substrate 100 was coated according to the method described in one of the preceding figures and which, due to its hydrophobic surface quality, prevents the sample liquid 10 introduced, for example, via the channel 161 into the space 156 from passing through the capillary column optionally present between the carrier element 150 and the cover element 160. For this purpose, the cover element 160 according to this exemplary embodiment in particular has a non-polar, hydrophobic or only slightly hydrophilic surface quality so that when the, for example aqueous, sample liquid 10 contacts the surface of the cover element 160, which is, for example, formed as a polymer substrate, a correspondingly large contact angle 11 forms, which counteracts undesired fluidic cross-talk across the column between different liquid-conducting hydrophilic regions, formed as a hydrophilic layer 105, on the top side of the carrier element 150.

According to this exemplary embodiment, the carrier module 500 comprises a venting channel 162 that is in particular integrated in the cover element 160 and via which a displacement of a gaseous medium 20 present in the carrier module 500 is possible according to this exemplary embodiment. Regardless, venting can also be realized via a further channel 163 in the cover element 160. The channel 163 is also only optionally provided for a (return) transport of the sample liquid 10 from the carrier element 150 into the cover element 160. Furthermore optionally, the carrier module 500 according to this exemplary embodiment can be used for use with a further liquid 30, which in particular cannot be mixed with the sample liquid 10. Here, a microfluidic pumping apparatus for transporting the sample liquid 10 is integrated or integrable into the cover element 160. According to an exemplary embodiment, the pumping apparatus is actuated via an interface to a processing unit. The pumping apparatus is in particular realized by means of an elastic membrane, wherein the pumping apparatus is actuated by means of the external processing unit via the application of at least two different pressure levels to a pneumatic interface to the cover element 160.

According to this exemplary embodiment, the cross-sections of the channels 161, 163 have, for example, dimensions that are in a range between 100×100 μm² to 2×2 mm², for example. However, preferably, according to this exemplary embodiment, the channels 161, 162, 163 are 300×300 μm² to 800×800 μm². For example, the recesses 200 furthermore have a size of between 1×1×1 μm² and 1×1×1 mm² and preferably between 10×10×10 μm² and 500×500×500 μm².

The cover element 160 is inexpensively manufactured from at least one polymer material according to this exemplary embodiment. The one or optionally a plurality of further microstructured component(s) forms, optionally in combination with the at least one carrier element 150, a lab-on-chip cartridge. In particular, the carrier module 500 has the following advantages:

Combining a carrier element 150 with at least one cover element 160 provides termination and/or delimitation of the space present over the chip top side of the carrier element 150. This avoids, in particular in the case of a hydrophobic or only slightly hydrophilic surface quality of the cover element 160, aqueous solutions in particular crossing the regions of the carrier element 150 with a hydrophobic surface quality due to the capillary pressure building there. In this way, processing of aqueous solutions in the hydrophilic regions and the etched structures of the carrier element 150 is enabled, wherein the hydrophobic regions of the surface serve as a barrier and can be used to guide the sample liquid. By the approach presented herein, a simple microfluidic integration of a carrier element produced according to the method into a microfluidic environment made of polymer material is allowed. By using polymer materials to form the cover element 160, both inexpensive manufacturing of the carrier module 500 in high volumes, for example by using high throughput methods, such as injection molding and laser welding of polymer components, and processing of larger fluid volumes in the range of a few tens or hundreds of microliters in the carrier module 500, which are used, for example, for performing molecular diagnostic test procedures, are possible.

FIG. 8 shows a flow chart of a method 800 for using a carrier element 500 according to one exemplary embodiment. The method 800 comprises a step 805 of bringing the sample liquid into contact with the cover element 160 and a step 810 of bringing the sample liquid into contact with a surface of the carrier element 150. The carrier element used in the method 800 may, for example, correspond or be similar to the carrier element described in one of FIGS. 3 to 7. Furthermore, the carrier element used may have been produced by a method as described in one of FIG. 1 or 2.

FIG. 9 is a block diagram of an apparatus 900 according to one exemplary embodiment. The apparatus 900 is designed to actuate or carry out a method for producing a carrier element for receiving a sample liquid, as described in one of FIG. 1 to 3 or 5. The apparatus 900 comprises a unit 905 for coating a carrier substrate with a light-sensitive polymer layer in order to obtain a coated carrier substrate, in particular wherein the carrier substrate has a hydrophilic surface quality. Furthermore, the apparatus 900 comprises a unit 910 for exposing and developing the coated carrier substrate in order to obtain a structured polymer layer, and a unit 915 for fluorinating the structured polymer layer arranged on the carrier substrate, in order to produce the carrier element for receiving the sample liquid, in particular wherein the structured polymer layer obtains a hydrophobic surface quality as a result of the fluorination step.

If an exemplary embodiment encompasses an “and/or” conjunction between a first feature and a second feature, this is to be read such that the exemplary embodiment according to one embodiment comprises both the first feature and the second feature and according to a further embodiment comprises either only the first feature or only the second feature.

1. A method for producing a carrier element for receiving a sample liquid, comprising:
coating a carrier substrate with a light-sensitive polymer layer in order to obtain a coated carrier substrate, wherein the carrier substrate (100) has a hydrophilic surface quality;
exposing and developing the coated carrier substrate in order to obtain a structured polymer layer; and
fluorinating the structured polymer layer arranged on the carrier substrate in order to produce the carrier element for receiving the sample liquid, wherein the structured polymer layer obtains a hydrophobic surface quality as a result of the fluorinating step being performed.

2. The method according to claim 1, wherein the carrier substrate is at least partially formed from a semiconductor material.

3. The method according to claim 1, further comprising structuring the carrier substrate in order to obtain at least one recess in the carrier substrate.

4. The method according to claim 3, wherein:
the structuring step, includes generating a passivation layer on at least one side wall of the at least one recess, and
the fluorination step includes at least partially removing the passivation layer.

5. The method according to claim 1, wherein the coating step includes using as the carrier substrate:
a substrate having an oxide layer, and/or
a carrier substrate coated with an adhesive-agent layer.

6. The method according to claim 1, further comprising:
applying a further light-sensitive polymer layer, and
further exposing and developing the further polymer layer in order to obtain a further structured polymer layer.

7. The method according to claim 6, further comprising:
further structuring after the further exposure and development step in order to obtain at least one further structuring.

8. The method according to claim 1, further comprising:
depositing a layer after the fluorinating step in order to alter and/or cover a surface of the carrier substrate.

9. A control unit configured to carry out and/or actuate the steps of the method according to claim 1 in corresponding units.

10. A computer program configured to carry out and/or actuate the steps of the method according to claim 1.

11. A machine-readable storage medium on which the computer program product according to claim 10 is stored.

12. A carrier element for receiving a sample liquid, the carrier element comprising:
a carrier substrate having a hydrophilic surface quality; and
a polymer layer arranged on the carrier substrate and having a hydrophobic surface quality.

13. A carrier module, comprising:
a carrier element according to claim 12 for receiving a sample liquid; and
a cover element connected to the carrier element and designed to apply the sample liquid to the carrier element.

14. The method for using a carrier module according to claim 13, further comprising, during use of the carrier module:
bringing a sample liquid into contact with the cover element, and/or
bringing the sample liquid into contact with a surface of the carrier element.

15. An apparatus designed to carry out, actuate, and/or implement the steps of claim 1 in corresponding units.

16. The method according to claim 2, wherein the semiconductor material is a silicon-containing material.

17. The method according to claim 7, wherein the at least one further structuring includes structuring of an oxide layer present on the carrier substrate.
